(19) United States
(12) Patent Application Publication
(10) Pub. No.: US 2025/0131232 A1
(43) Pub. Date: Apr. 24, 2025

(54) CIRCUIT STRUCTURE AND CARD-SHAPE DEVICE COMPRISING THE SAME

(71) Applicant: ARTIFICIAL INTELLIGENCE CO., LTD., TAIPEI CITY (TW)

(72) Inventor: CHE-WEI LIN, HSINCHU CITY (TW)

(21) Appl. No.: 18/490,789

(22) Filed: Oct. 20, 2023

(51) Int. Cl. G06K 19/077; G06F 13/40; G06K 19/073; H05K 1/18

(52) U.S. Cl. CPC G06K 19/07722; G06K 19/073; G06K 19/07745; H05K 1/181; H05K 1/189; G06F 13/4068; G06F 2213/0042

(57) ABSTRACT

The present invention provides a circuit structure and a card-shape device comprising the same. The card-shape device includes a first plate, a second plate, a frame and the circuit structure. The frame is disposed between the first plate and the second plate. An accommodating space is defined by the first plate, the second plate and the frame. The circuit structure is disposed in the accommodating space. The circuit structure includes a flexible printed circuit and an interface element. The flexible printed circuit has a first recess and first electrical contacts disposed around the first recess. The interface element has a body, an interface disposed on the body and second electrical contacts disposed on the body and electrically connected with the interface. The interface of the interface element is exposed to the first recess of the flexible printed circuit when the first electrical contacts electrically connect to the second electrical contacts.

### BACKGROUND

### Field of the Invention

The present invention relates generally to a user card, in particular, to a user card having electronic components.

### Description of Related Art

Currently, there are a variety of user cards on the market. For example, there are some payment cards (e.g., credit cards, debit cards, charge cards, prepaid cards, etc.), and some personal cards (e.g., identification cards, drive license cards, health insurance cards, etc.). All these user cards are private and the information therein are confidential. However, once the user cards are lost or stolen, finding them back is difficult.

### BRIEF SUMMARY OF THE INVENTION

Some embodiments of the present invention provide a circuit structure. The circuit structure includes a flexible printed circuit and an interface element. The flexible printed circuit has a first recess and a plurality of first electrical contacts disposed around the first recess. The interface element has a body, an interface and a plurality of second electrical contacts. The interface is disposed on the body. The second electrical contacts are disposed on the body and electrically connected with the interface. The interface of the interface element is exposed to the first recess of the flexible printed circuit when the first electrical contacts electrically connect to the second electrical contacts.

In some embodiments, the interface of the interface element includes a universal serial bus type-c interface.

In some embodiments, the interface of the interface element receives an outside interface along a direction, and the first electrical contacts disposed around the first recess along the same direction.

In some embodiments, the flexible printed circuit further has a protrusion protruded from a surface of the flexible printed circuit, and the interface element further has a through hole or a second recess for receiving the protrusion of the flexible printed circuit.

Some embodiments of the present invention provide a card-shape device. The card-shape device includes a first plate, a second plate, a frame and the circuit structure. The frame is disposed between the first plate and the second plate. An accommodating space is defined by the first plate, the second plate and the frame. The circuit structure is disposed in the accommodating space.

In some embodiments, a gap is formed on the frame for exposing the interface of the of the interface element.

In some embodiments, the card-shape device further includes a battery and an electronic component. The battery is disposed in the accommodating space and connected with the circuit structure. The electronic component is disposed on the flexible printed circuit and powered by the battery.

In some embodiments, the first plate includes a portion which corresponds to a switch of the electronic component.

In some embodiments, the switch is a segment of the first plate.

In some embodiments, the electronic component includes a tracker.

In some embodiments, a hole is formed on the first plate or the second plate for exposing an antenna of the tracker.

In some embodiments, the electronic component includes a speaker, and a cavity is formed between the speaker and the flexible printed circuit.

In some embodiments, the card-shape device includes a chip. The chip is configured to record personal information.

In some embodiments, the first plate attaches to the frame by an adhesive disposed around a first surface of the frame, and the second plate attaches to the frame by another adhesive disposed around a second surface of the frame.

In some embodiments, the card-shape device has a rectangular shape, a round shape or a triangular shape.

In some embodiments, the frame has a ring shape.

In some embodiments, the frame has a uniform width.

In some embodiments, the uniform width is between 1 mm to 10 mm.

In some embodiments, the thickness of the first plate is between 0.1 mm to 0.5 mm, the thickness of the second plate is between 0.1 mm to 0.5 mm and the thickness of the frame is between 0.3 mm to 2 mm.

In some embodiments, the thickness of the card-shape device is between 0.5 mm to 3 mm.

### BRIEF DESCRIPTION OF THE DRAWINGS

Aspects of the present invention are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a three-dimensional diagram of a card-shape device according to some embodiments of the present invention.

FIG. 1B is an explosion diagram of the card-shape device according to some embodiments of the present invention.

FIG. 1C is cross-sectional view of the card-shape device according to some embodiments of the present invention.

FIG. 2A is a three-dimensional diagram of a card-shape device according to some embodiments of the present invention.

FIG. 2B is an explosion diagram of the card-shape device according to some embodiments of the present invention.

FIG. 2C is cross-sectional view of the card-shape device according to some embodiments of the present invention.

FIG. 3A is a three-dimensional diagram of a card-shape device according to some embodiments of the present invention.

FIG. 3B is an explosion diagram of the card-shape device according to some embodiments of the present invention.

FIG. 3C is cross-sectional view of the card-shape device according to some embodiments of the present invention.

FIG. 4A is a three-dimensional diagram of a card-shape device according to some embodiments of the present invention.

FIG. 4B is an explosion diagram of the card-shape device according to some embodiments of the present invention.

FIG. 4C is a three-dimensional diagram of a circuit structure of the card-shape device according to some embodiments of the present invention.

FIG. 4D is an explosion diagram of the circuit structure of the card-shape device according to some embodiments of the present invention.

FIG. 4E is a three-dimensional diagram of an interface element of the circuit structure according to some embodiments of the present invention.

FIG. 4F is cross-sectional view of the card-shape device according to some embodiments of the present invention.

FIG. 5A is a three-dimensional diagram of a circuit structure according to some embodiments of the present invention.

FIG. 5B is an explosion diagram of the circuit structure according to some embodiments of the present invention.

FIG. 5C is a three-dimensional diagram of an interface element of the circuit structure according to some embodiments of the present invention.

FIG. 6A is a three-dimensional diagram of a card-shape device according to some embodiments of the present invention.

FIG. 6B is an explosion diagram of the card-shape device according to some embodiments of the present invention.

FIG. 6C is a three-dimensional diagram of a circuit structure of the card-shape device according to some embodiments of the present invention.

FIG. 6D is an explosion diagram of the circuit structure of the card-shape device according to some embodiments of the present invention.

FIG. 6E is a three-dimensional diagram of an interface element of the circuit structure according to some embodiments of the present invention.

FIG. 6F is cross-sectional view of the card-shape device according to some embodiments of the present invention.

### DETAILED DESCRIPTION

The following description of the disclosure accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present invention completely comprehensible, detailed steps and structures are provided in the following description. Obviously, implementation of the present invention does not limit special details known by persons skilled in the art. In addition, known structures and steps are not described in detail, so as not to unnecessarily limit the present invention. Preferred embodiments of the present invention will be described below in detail. However, in addition to the detailed description, the present invention may also be widely implemented in other embodiments. The scope of the present invention is not limited to the detailed description, and is defined by the claims.

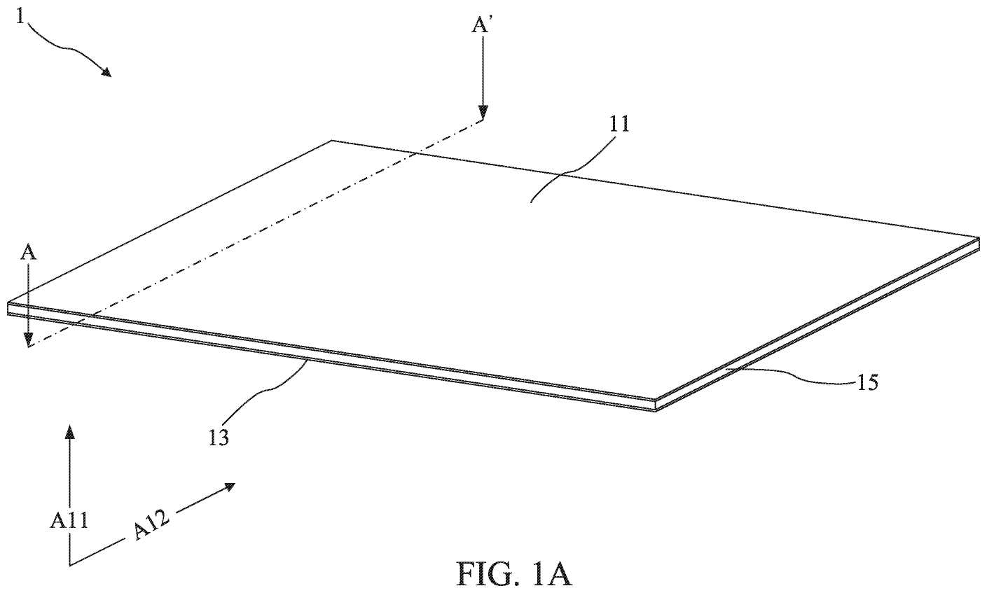

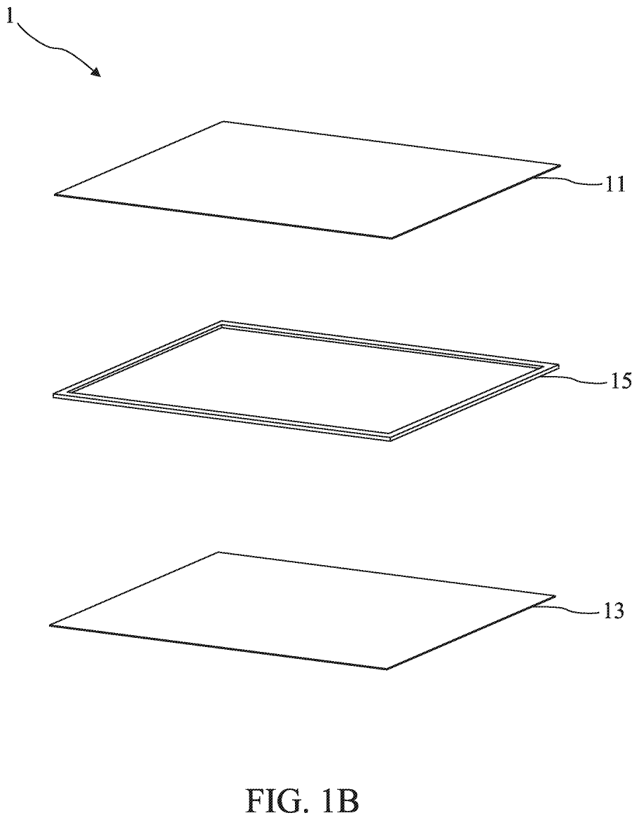

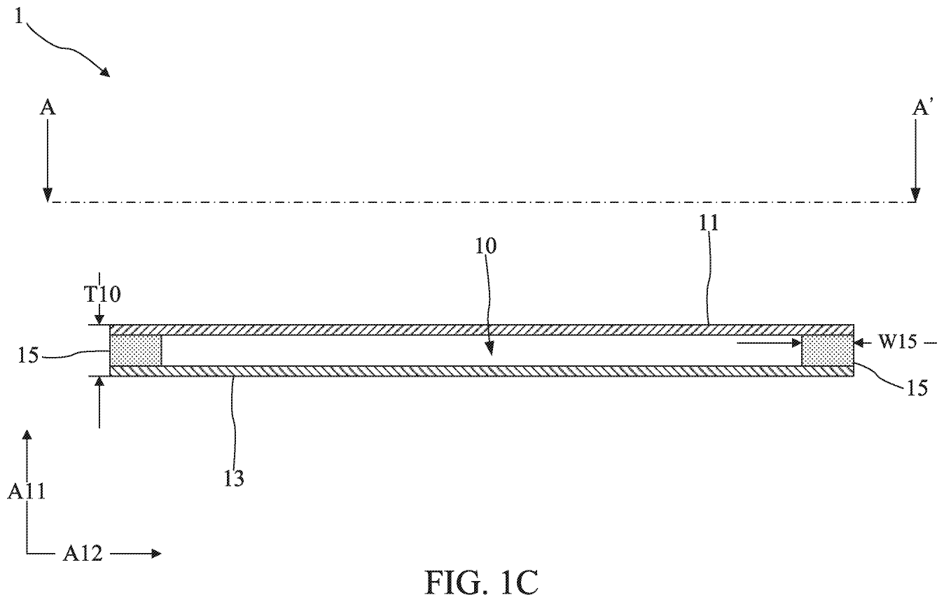

Please refer to FIG. 1A to FIG. 1C. FIG. 1A is a three-dimensional diagram of a card-shape device 1 according to some embodiments of the present invention. FIG. 1B is an explosion diagram of the card-shape device 1 according to some embodiments of the present invention. FIG. 1C is a cross-sectional view of the card-shape device 1 according to some embodiments of the present invention.

In particular, the card-shape device 1 includes a first plate 11, a second plate 13 and a frame 15. The first plate 11, the second plate 13 and the frame 15 define an accommodating space 10. More specifically, the accommodating space 10 is defined by the first plate 11, the second plate 13 and the frame 15 when the first plate 11, the second plate 13 and the frame 15 are assembled.

In some embodiments, the accommodating space 10 is sealed by the first plate 11, the second plate 13 and the frame 15. In some embodiments, the accommodating space 10 is not completely sealed by the first plate 11, the second plate 13 and the frame 15.

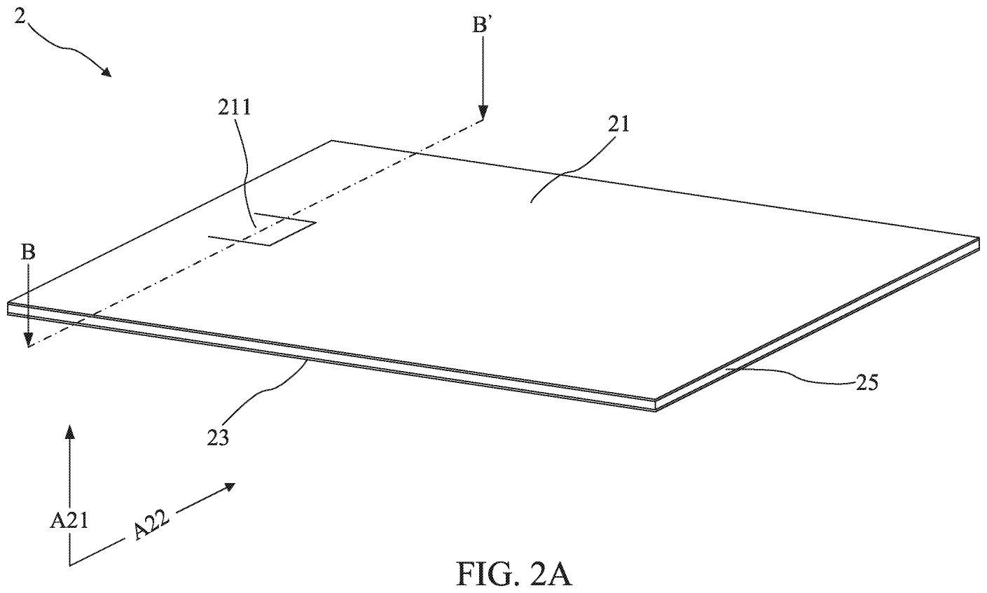

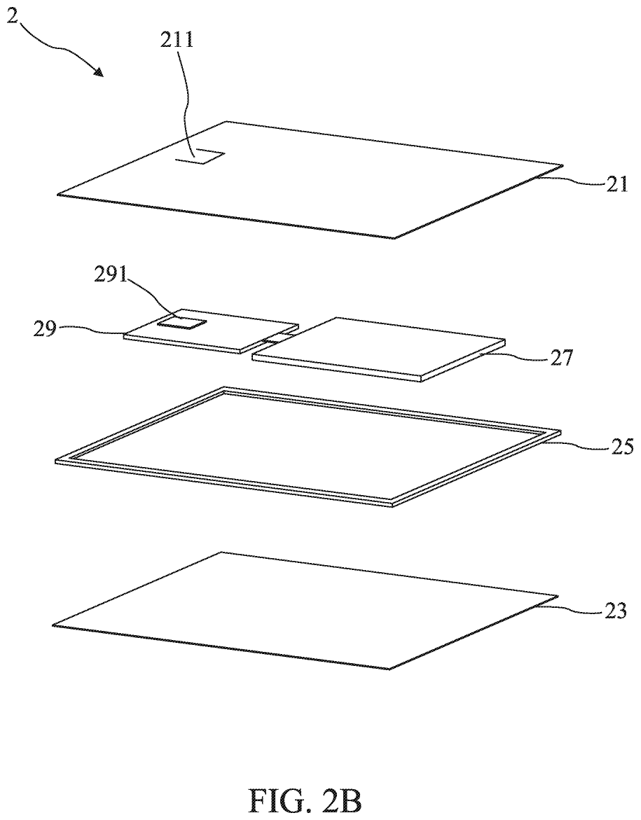

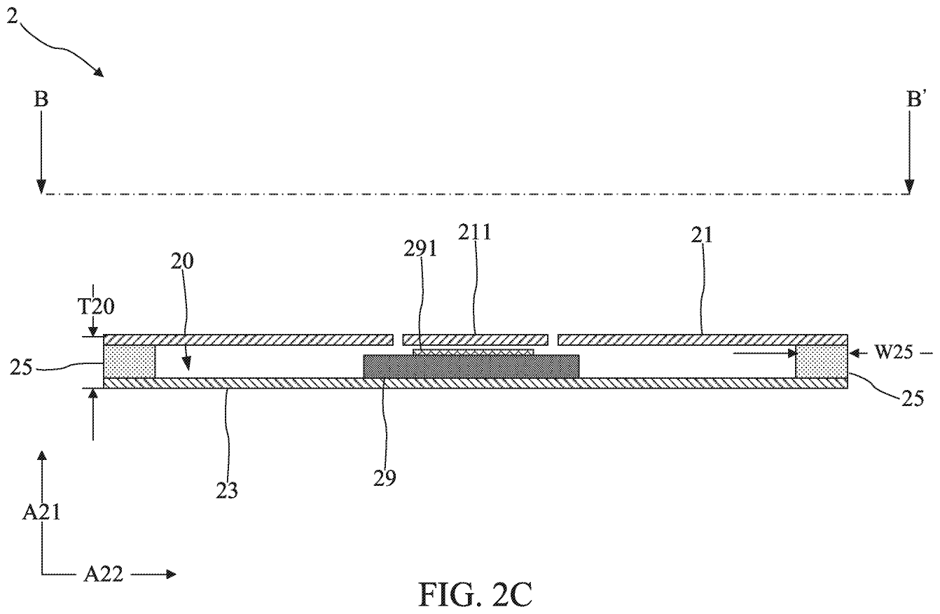

Please refer to FIG. 2A to FIG. 2C. FIG. 2A is a three-dimensional diagram of a card-shape device 2 according to some embodiments of the present invention. FIG. 2B is an explosion diagram of the card-shape device 2 according to some embodiments of the present invention. FIG. 2C is a cross-sectional view of the card-shape device 2 according to some embodiments of the present invention.

In particular, the card-shape device 2 includes a first plate 21, a second plate 23, a frame 25, a battery 27 and an electronic component 29. The first plate 21, the second plate 23 and the frame 25 define an accommodating space 20. More specifically, the accommodating space 20 is defined by the first plate 21, the second plate 23 and the frame 25 when the first plate 21, the second plate 23 and the frame 25 are assembled. The battery 27 and the electronic component 29 are disposed in the accommodating space 20. The electronic component 29 is electrically connected to the battery 27, and is powered by the battery 27.

In some embodiments, the first plate 21 includes a portion 211. The portion 211 is a part of the first plate 21 and corresponds to a switch 291 of the electronic component 29. In particular, the portion 211 is a segment of the first plate 21. More specifically, as shown in FIGS. 2A to 2C, an area of the first plate 21 is partially segmented into the portion 211. The portion 211 is still attached to the first plate 21 because the portion 211 is not completely segmented from the first plate 21. Accordingly, when a user presses the portion 211, it may cause the portion 211 to lean against the corresponding switch 291 of the electronic component 29 to control the activation or inactivation of the electronic component 29.

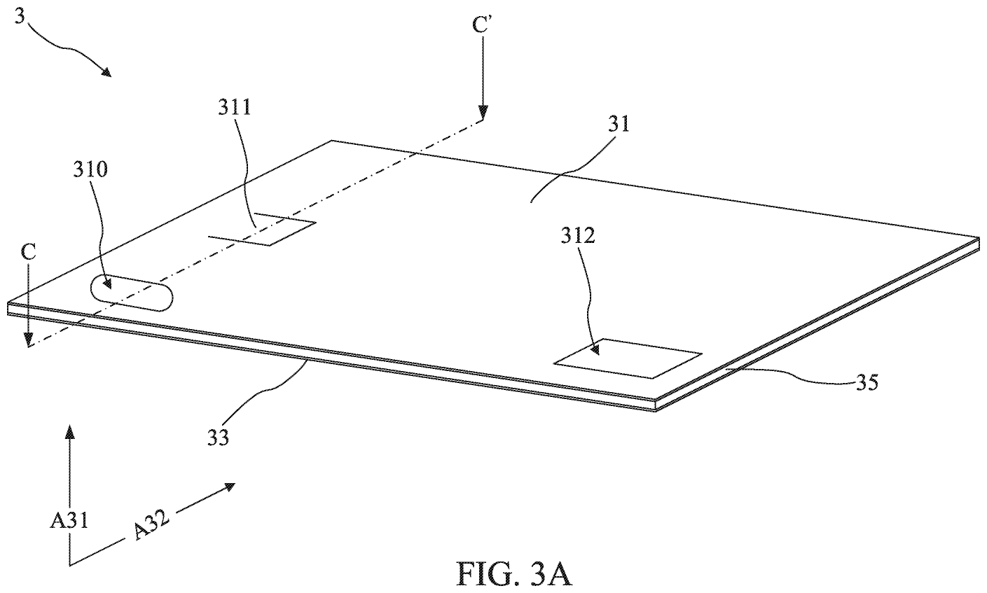

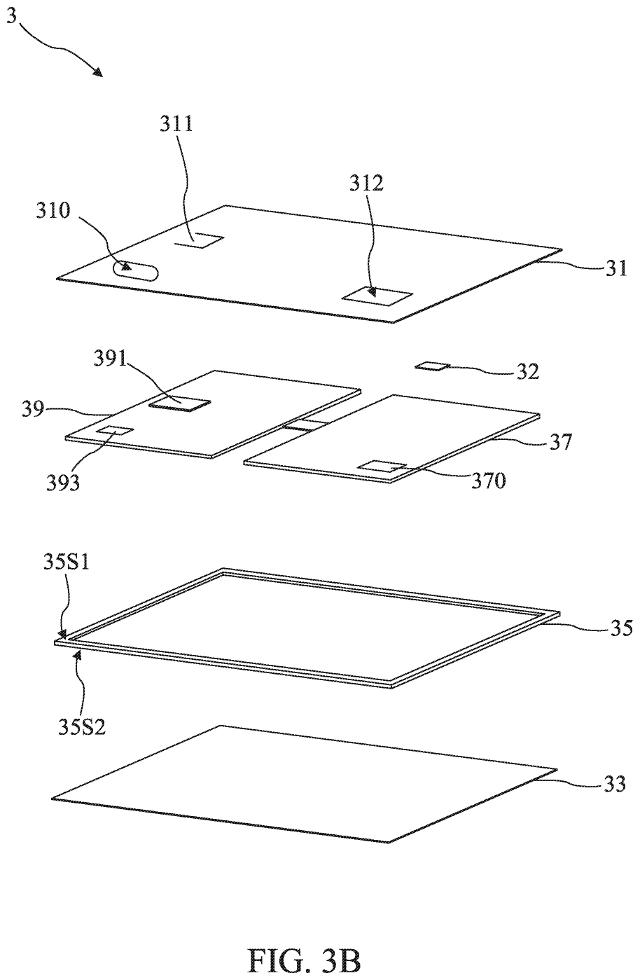

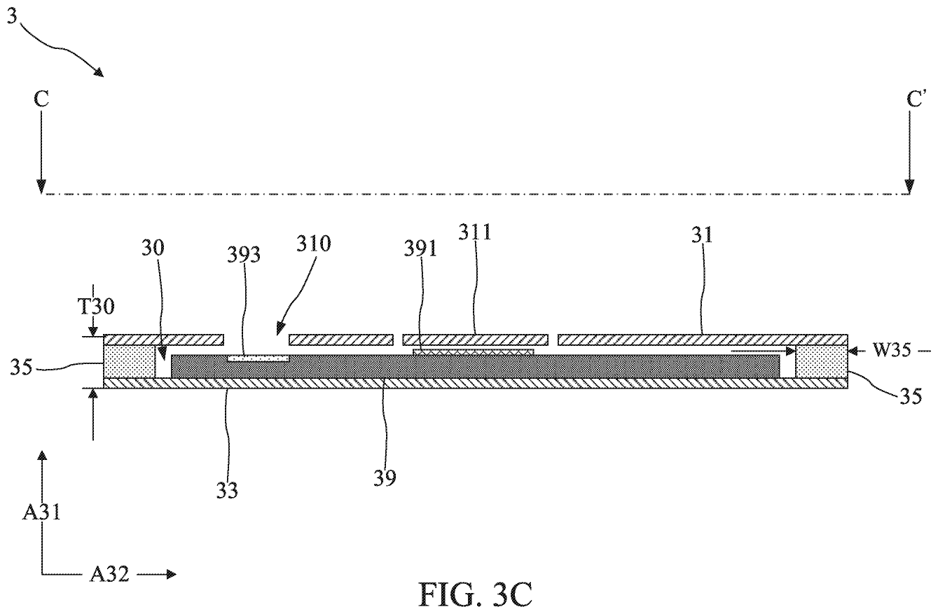

Please refer to FIG. 3A to FIG. 3C. FIG. 3A is a three-dimensional diagram of a card-shape device 3 according to some embodiments of the present invention. FIG. 3B is an explosion diagram of the card-shape device 3 according to some embodiments of the present invention. FIG. 3C is a cross-sectional view of the card-shape device 3 according to some embodiments of the present invention.

In particular, the card-shape device 3 includes a first plate 31, a second plate 33, a frame 35, a battery 37, an electronic component 39 and a chip 32. The first plate 31, the second plate 33 and the frame 35 define an accommodating space 30. More specifically, the accommodating space 30 is defined by the first plate 31, the second plate 33 and the frame 35 when the first plate 31, the second plate 33 and the frame 35 are assembled. The battery 37, the electronic component 39 and the chip 32 are disposed in the accommodating space 30. The chip 32 is configured to record personal information (e.g., credit card information, debit card information, charge card information, prepaid card information, identification card information, drive license card information, health insurance card information, etc.). The electronic component 39 is electrically connected to the battery 37, and is powered by the battery 37.

In some embodiments, the first plate 31 includes a portion 311. The portion 311 is a part of the first plate 31. The portion 311 corresponds to a switch 391 of the electronic component 39. In other words, the location of the portion 311 formed on the first plate 311 corresponds to the location of the switch 391 of the electronic component 39 disposed in the accommodating space 30.

In particular, the portion 311 is a segment of the first plate 31. More specifically, as shown in FIGS. 3A to 3C, an area of the first plate 31 is partially segmented into the portion 311. The portion 311 is still attached to the first plate 31 because the portion 311 is not completely segmented from the first plate 31. Accordingly, when a user presses the portion 311, it may cause the portion 311 to lean against the corresponding switch 391 of the electronic component 39 to control the activation or inactivation of the electronic component 39.

In some embodiments, materials of the first plate 31, the second plate 33 and the frame 35 include metal or plastic. In some embodiments, the electronic component 39 includes a tracker having an antenna 393. To prevent the antenna 393 from being shielded (especially when the first plate 31, the second plate 33 and the frame 35 are made of metal), a hole 310 is formed on the first plate 31 for exposing the antenna 393. In other words, the location of the hole 310 formed on the first plate 31 corresponds to the location of the antenna 393 of the electronic component 39 disposed in the accommodating space 30.

In some embodiments, the battery 37 is rechargeable. Accordingly, a hole 312 is formed on the first plate 310 for exposing a charging slot 370 of the battery 37. In other words, the location of the hole 312 formed o the first plate 31 corresponds to the location of the charging slot 370 of the battery 37 disposed in the accommodating space 30.

It should note that, in some embodiments, the holes for exposing the antenna of the electronic component and the charging slot of the battery may be formed on the second plate 33 when the antenna of the electronic component and the charging slot of the battery face to the second plate 33.

In some embodiments, the first plate 31 attaches to the frame 35 by an adhesive (not shown) disposed around a first surface 35S1 of the frame 35, and the second plate 33 attaches to the frame 35 by another adhesive (not shown) disposed around a second surface 35S2 of the frame 35.

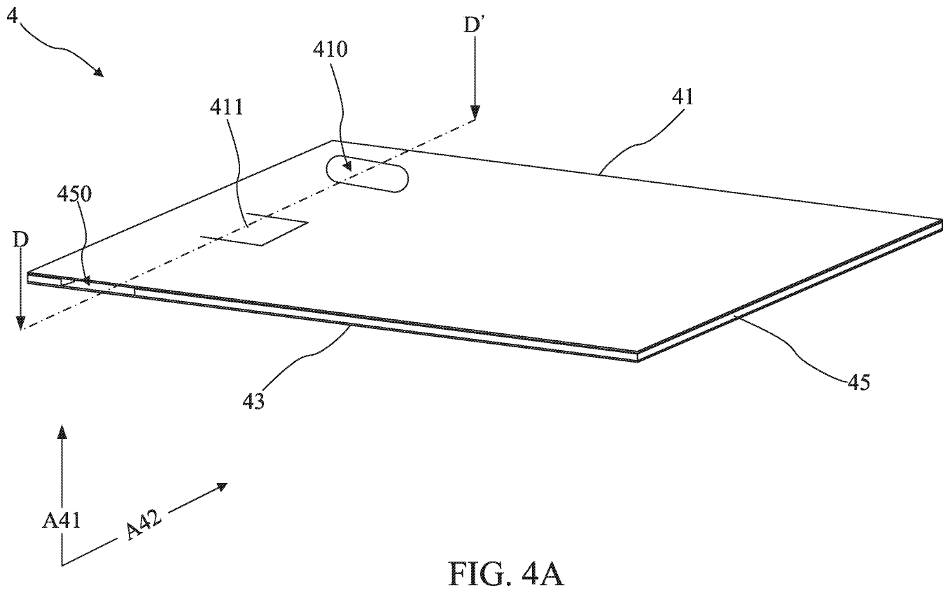

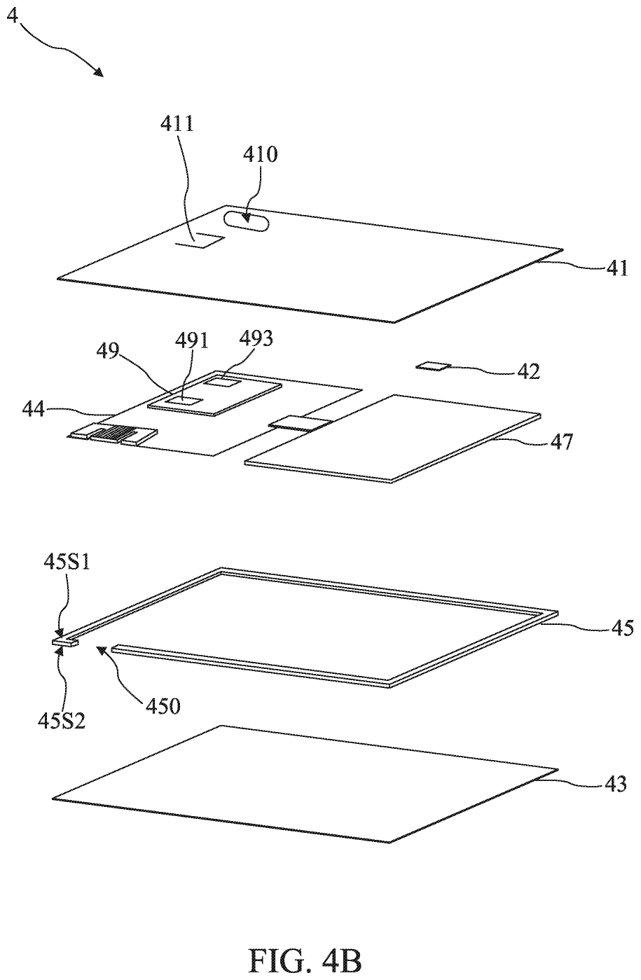

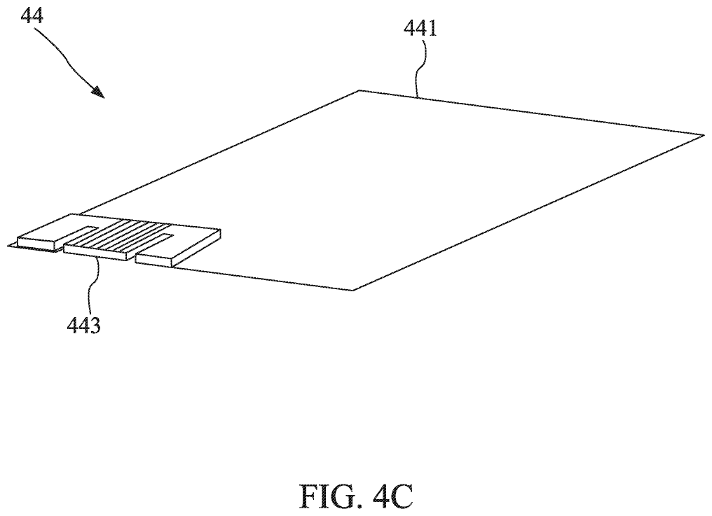

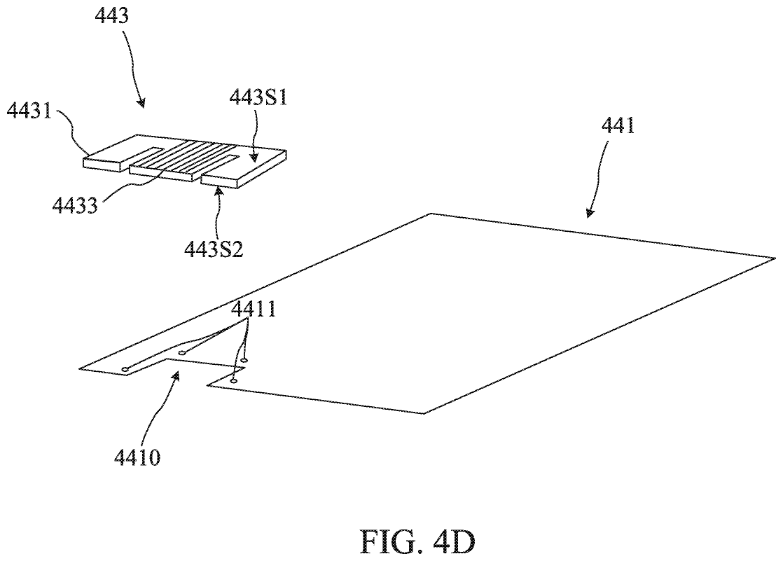

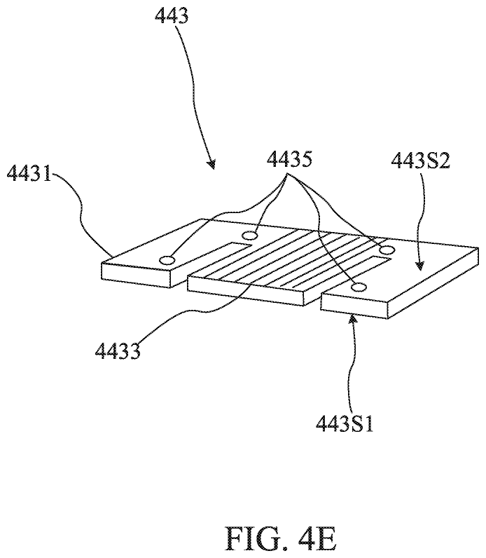

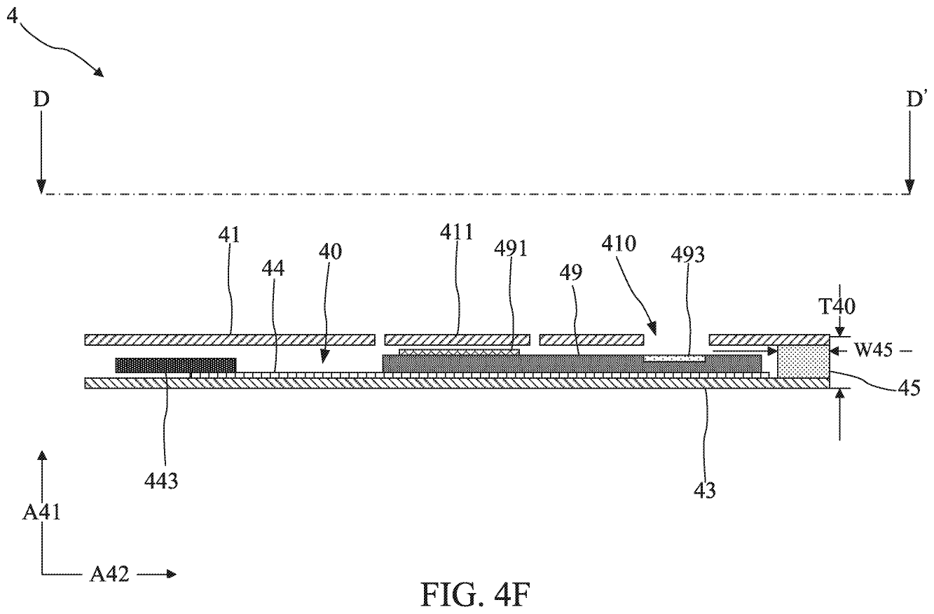

Please refer to FIG. 4A to FIG. 4F. FIG. 4A is a three-dimensional diagram of a card-shape device 4 according to some embodiments of the present invention. FIG. 4B is an explosion diagram of the card-shape device 4 according to some embodiments of the present invention. FIG. 4C is a three-dimensional diagram of a circuit structure 44 of the card-shape device 4 according to some embodiments of the present invention. FIG. 4D is an explosion diagram of the circuit structure 44 according to some embodiments of the present invention. FIG. 4E is a three-dimensional diagram of an interface element 443 of the circuit structure 4 according to some embodiments of the present invention.

FIG. 4F is a cross-sectional view of the card-shape device 4 according to some embodiments of the present invention.

In particular, the card-shape device 4 includes a first plate 41, a second plate 43, a frame 45, a battery 47, an electronic component 49, a chip 42 and the circuit structure 44. The first plate 41, the second plate 43 and the frame 45 define an accommodating space 40. More specifically, the accommodating space 40 is defined by the first plate 41, the second plate 43 and the frame 45 when the first plate 41, the second plate 43 and the frame 45 are assembled. The battery 47, the electronic component 49, the chip 42 and the structure 44 are disposed in the accommodating space 40. The chip 42 is configured to record personal information (e.g., credit card information, debit card information, charge card information, prepaid card information, identification card information, drive license card information, health insurance card information, etc.).

In some embodiments, the circuit structure 44 includes a flexible printed circuit 441 and an interface element 443. The flexible printed circuit 441 has a first recess 4410 and a plurality of first electrical contacts 4411. The first electrical contacts 4411 are disposed around the first recess 4410. The interface element 443 has a body 4431 with a first surface 443S1 and a second surface 443S2, an interface 4433 and a plurality of second electrical contacts 4435. The interface 4433 is disposed on the body 4431. The second electrical contacts 4435 are disposed on the body 4431 and electrically connected with the interface 4433.

In some embodiments, the flexible printed circuit 441 and the interface element 443 are assembled and the first electrical contacts 4411 electrically connect to the second electrical contacts 4435 one-to-one. When the flexible printed circuit 441 and the interface element 443 are assembled and the first electrical contacts 4411 electrically connect to the second electrical contacts 4435, the interface 4433 of the interface element 443 is exposed to the first recess 4410 of the flexible printed circuit 441.

In some embodiments, a gap 450 is formed on the frame 45. When the interface element 443 is disposed in the accommodating space 40, the position of the gap 450 corresponds to the position of the interface 4433 of the interface element 443 so that the interface 4433 is exposed to the gap 450. Accordingly, the interface 4433 may receive an outside interface (not shown) through the gap 45.

In some embodiments, the battery 47 is disposed in the accommodating space 40 and electrically connected with the circuit structure 44. The electronic component 49 is disposed on the flexible printed circuit 441 and electrically connected with the flexible printed circuit 441. The elements, which includes the electronic component 49, disposed on and electrically connected to the flexible printed circuit 441 are all power by the battery 47. In some embodiments, the battery 47 is rechargeable.

In some embodiments, the interface 4433 of the interface element 443 exposed to the gap 450 of the frame 45 is used for receiving a charging source (not shown) to charge the battery 37. In some embodiments, the interface 4433 of the interface element 443 exposed to the gap 450 of the frame 45 is used for receiving an interface of an electronic device (not shown) to exchange data between the electronic component 49 and the electronic device.

In some embodiments, the first plate 41 includes a portion 411. The portion 411 is a part of the first plate 41. The portion 411 corresponds to a switch 491 of the electronic component 49. In other words, the location of the portion 411 formed on the first plate 411 corresponds to the location of the switch 491 of the electronic component 49 disposed in the accommodating space 40.

In particular, the portion 411 is a segment of the first plate 41. More specifically, as shown in FIGS. 4A, 4B and 4F, an area of the first plate 41 is partially segmented into the portion 411. The portion 411 is still attached to the first plate 41 because the portion 411 is not completely segmented from the first plate 41. Accordingly, when a user presses the portion 411, it may cause the portion 411 to lean against the corresponding switch 491 of the electronic component 49 to control the activation or inactivation of the electronic component 49.

In some embodiments, materials of the first plate 41, the second plate 43 and the frame 45 include metal or plastic. In some embodiments, the electronic component 49 includes a tracker having an antenna 493. To prevent the antenna 493 from being shielded (especially when the first plate 41, the second plate 43 and the frame 45 are made of metal), a hole 410 is formed on the first plate 41 for exposing the antenna 493. In other words, the location of the hole 410 formed on the first plate 41 corresponds to the location of the antenna 493 of the electronic component 49 disposed in the accommodating space 40. It should note that, in some embodiments, the holes for exposing the antenna of the electronic component may be formed on the second plate 43 when the antenna of the electronic component faces to the second plate 43.

In some embodiments, the first plate 41 attaches to the frame 45 by an adhesive (not shown) disposed around a first surface 45S1 of the frame 45, and the second plate 43 attaches to the frame 45 by another adhesive (not shown) disposed around a second surface 45S2 of the frame 45.

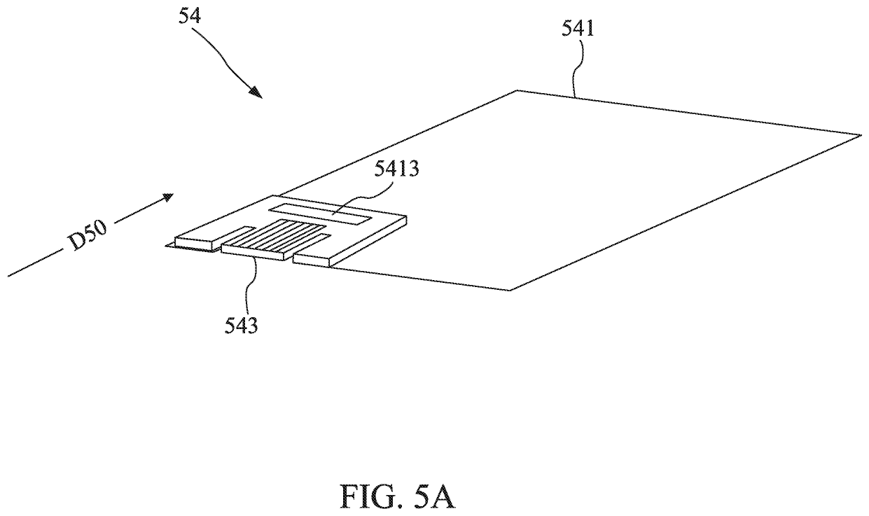

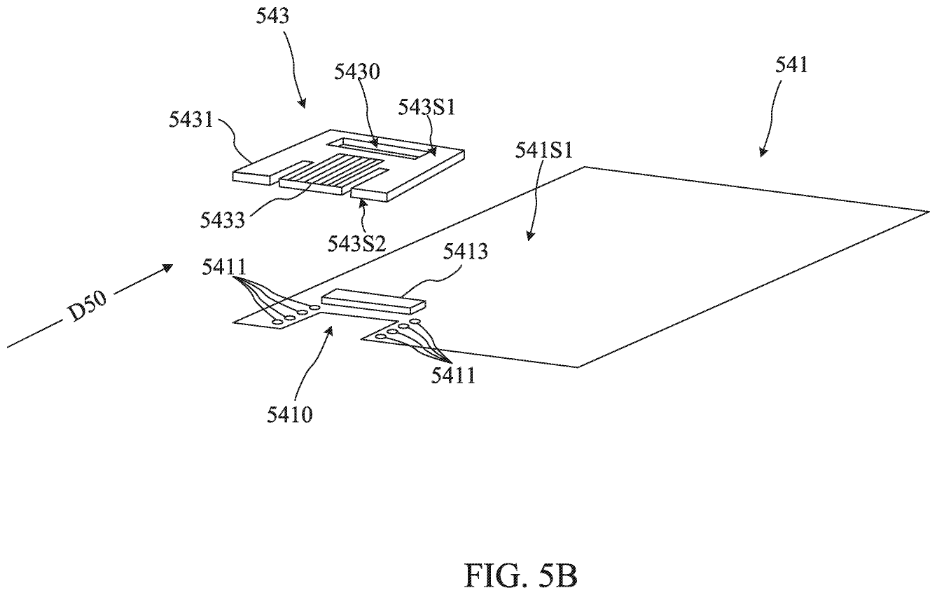

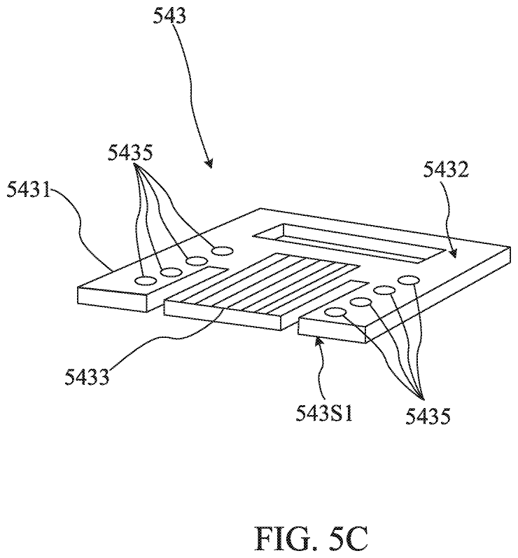

Please refer to FIG. 5A to FIG. 5C. FIG. 5A is a three-dimensional diagram of a circuit structure 54 according to some embodiments of the present invention. FIG. 5B is an explosion diagram of the circuit structure 54 according to some embodiments of the present invention. FIG. 5C is a three-dimensional diagram of an interface element 543 of the circuit structure 5 according to some embodiments of the present invention.

In some embodiments, the circuit structure 54 includes a flexible printed circuit 541 and an interface element 543. The flexible printed circuit 541 has a first recess 5410, a plurality of first electrical contacts 5411 and a protrusion 5413. The first electrical contacts 5411 are disposed around the first recess 5410. The protrusion 5413 protrudes from a surface 541S1 of the flexible printed circuit 541. The interface element 543 has a body 5431 with a first surface 543S1 and a second surface 543S2, an interface 5433, a plurality of second electrical contacts 5435 and a through hole 5430. The interface 5433 is disposed on the body 5431. The second electrical contacts 5435 are disposed on the body 5431 and electrically connected with the interface 5433. The through hole 5430 is formed for receiving the protrusion 5413. In some implementations, the through hole 5430 may be replaced by a recess faced toward the body 5431 for receiving the protrusion 5413.

In some embodiments, when the flexible printed circuit 541 and the interface element 543 are assembled, the first electrical contacts 5411 electrically connect to the second electrical contacts 5435 one-to-one and the through hole 5430 receives the protrusion 5413. Further, when the flexible printed circuit 541 and the interface element 543 are assembled, the first electrical contacts 5411 electrically connect to the second electrical contacts 4435 and the through hole 5430 receives the protrusion 5413, the interface 5433 of the interface element 543 is exposed to the first recess 5410 of the flexible printed circuit 541.

In some embodiments, the interface 5433 of the interface element 543 is used to receive an outside interface (not shown) along a direction D50, and the first electrical contacts 5411 is disposed along the same direction D50. For example, as shown in FIG. 5B, there are eight first electrical contacts 5411. Four of the first electrical contacts 5411 are disposed adjacent to one side of the first recess 5410 and along the same direction D50. Another four of the first electrical contacts 5411 are disposed adjacent to the other side of the first recess 5410 and along the same direction D50. Accordingly, after the first electrical contacts 5411 of the flexible printed circuit 541 electrically connect (e.g., by solder) to the second electrical contacts 5435 of the interface element 543, the stability and robustness of the combination between the flexible printed circuit 541 and the interface element 543 is enhanced.

In some embodiments, the protrusion 5413 is soldered on the flexible printed circuit 541 and includes magnetic material. Therefore, the protrusion 5413 may be used to attract a cover (not shown) used for protecting the interface 5433. In some embodiments, the interface 4433/5433 of the interface element 443/543 includes a universal serial bus (USB) type-c interface. For example, the interface 4433/5433 of the interface element 443/543 can be only the pinout interface of the USB type-c receptacle.

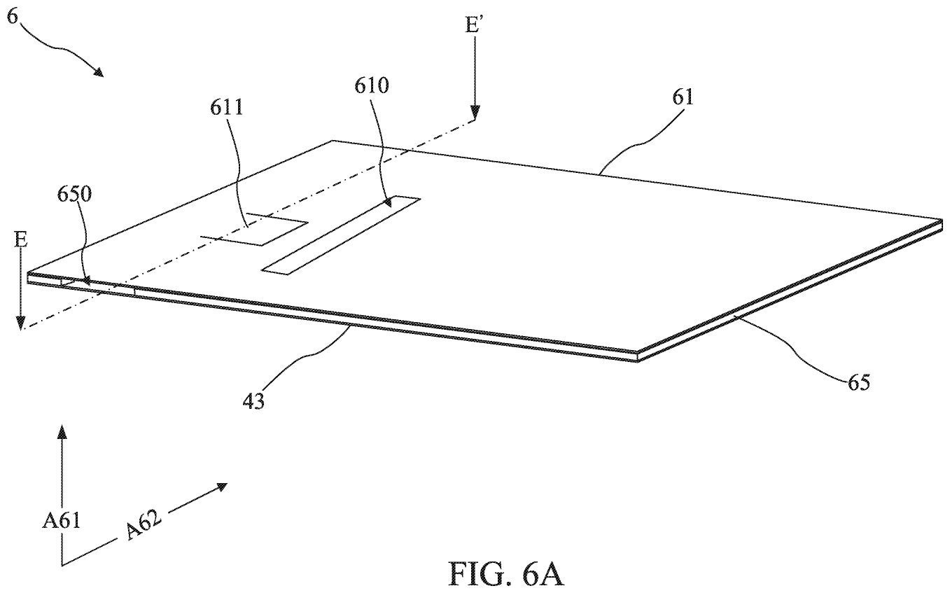

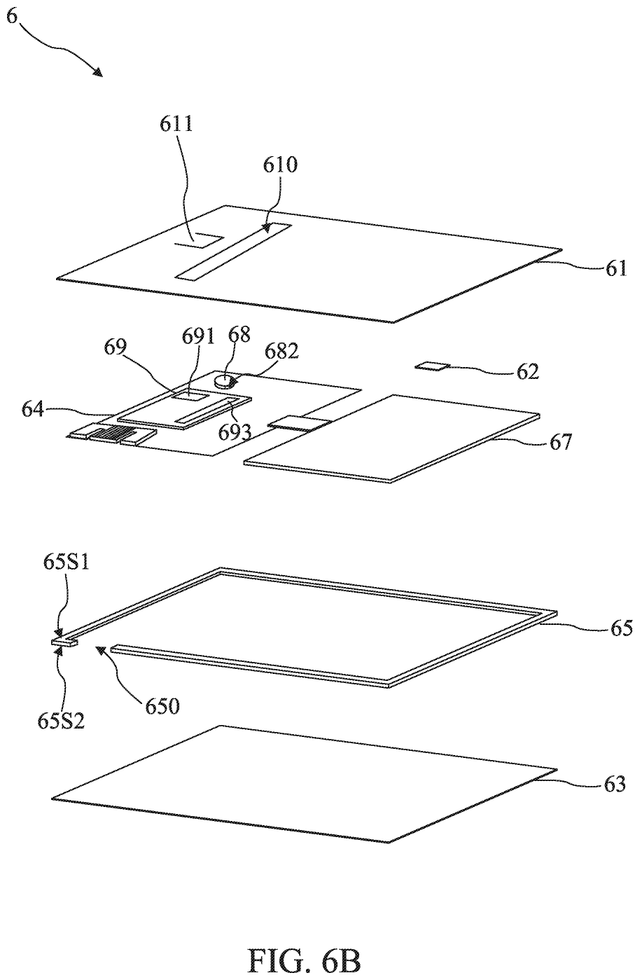

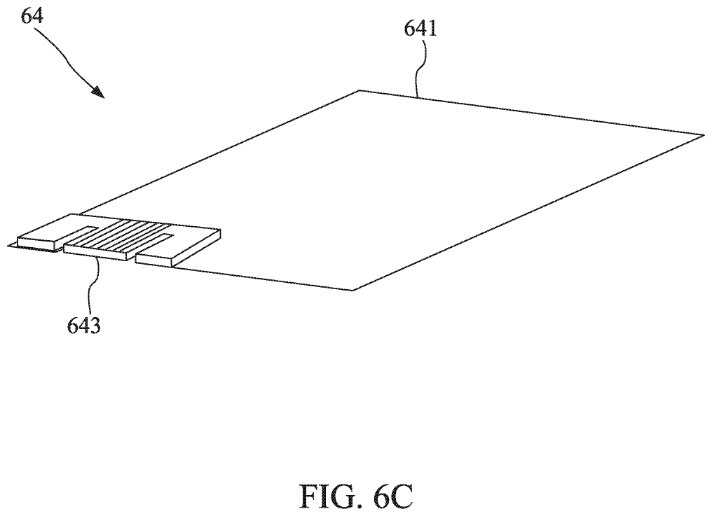

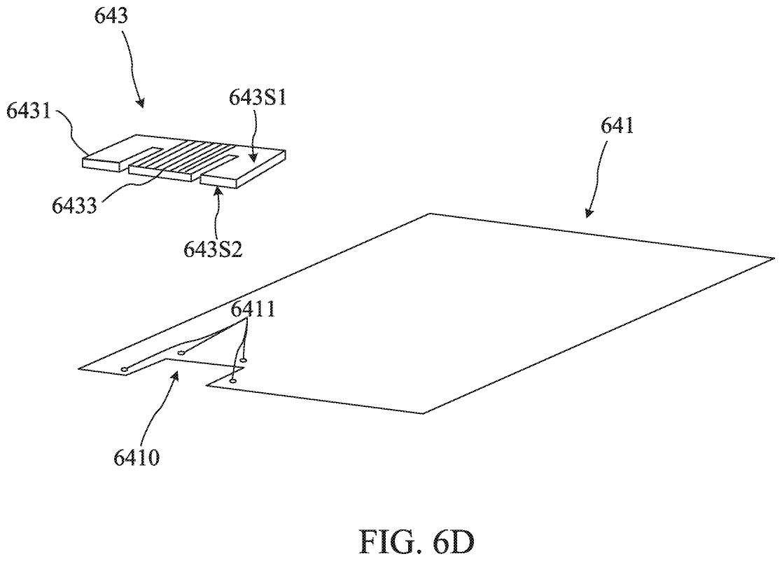

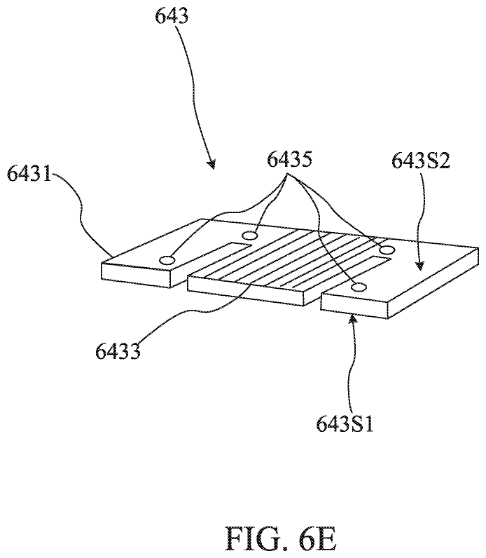

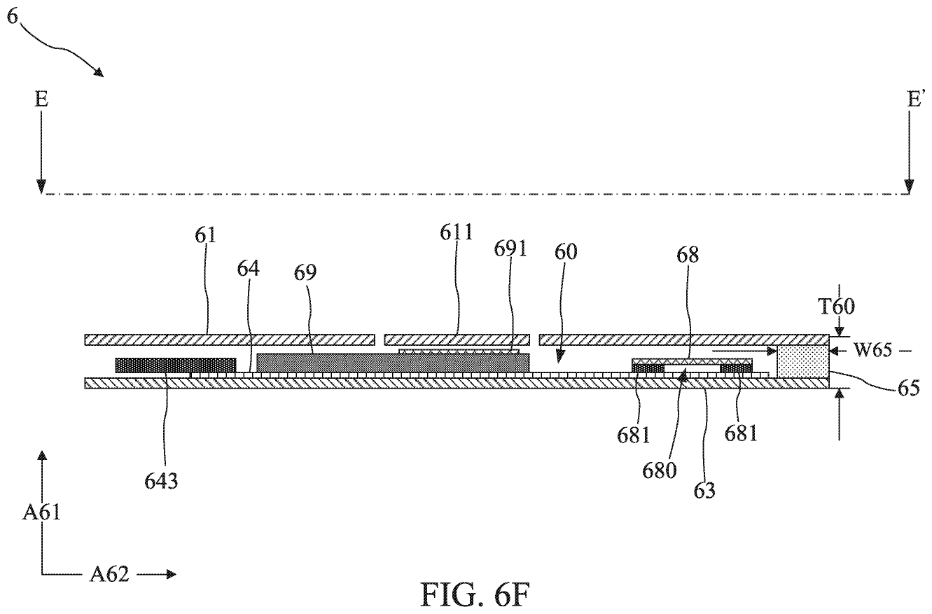

Please refer to FIG. 6A to FIG. 6F. FIG. 6A is a three-dimensional diagram of a card-shape device 6 according to some embodiments of the present invention. FIG. 6B is an explosion diagram of the card-shape device 6 according to some embodiments of the present invention. FIG. 6C is a three-dimensional diagram of a circuit structure 64 of the card-shape device 6 according to some embodiments of the present invention. FIG. 6D is an explosion diagram of the circuit structure 64 according to some embodiments of the present invention. FIG. 6E is a three-dimensional diagram of an interface element 643 of the circuit structure 6 according to some embodiments of the present invention. FIG. 6F is a cross-sectional view of the card-shape device 6 according to some embodiments of the present invention.

In particular, the card-shape device 6 includes a first plate 61, a second plate 63, a frame 65, a battery 67, an electronic component 69, a chip 62 and the circuit structure 64. The first plate 61, the second plate 63 and the frame 65 define an accommodating space 60. More specifically, the accommodating space 60 is defined by the first plate 61, the second plate 63 and the frame 65 when the first plate 61, the second plate 63 and the frame 65 are assembled. The battery 67, the electronic component 69, the chip 62 and the structure 64 are disposed in the accommodating space 60. The chip 62 is configured to record personal information (e.g., credit card information, debit card information, charge card information, prepaid card information, identification card information, drive license card information, health insurance card information, etc.).

In some embodiments, the circuit structure 64 includes a flexible printed circuit 641 and an interface element 643. The flexible printed circuit 641 has a first recess 6410 and a plurality of first electrical contacts 6411. The first electrical contacts 6411 are disposed around the first recess 6410. The interface element 643 has a body 6431 with a first surface 643S1 and a second surface 643S2, an interface 6433 and a plurality of second electrical contacts 6435. The interface 6433 is disposed on the body 6431. The second electrical contacts 6435 are disposed on the body 6431 and electrically connected with the interface 6433.

In some embodiments, the flexible printed circuit 641 and the interface element 643 are assembled and the first electrical contacts 6411 electrically connect to the second electrical contacts 6435 one-to-one. When the flexible printed circuit 641 and the interface element 643 are assembled and the first electrical contacts 6411 electrically connect to the second electrical contacts 6435, the interface 6433 of the interface element 643 is exposed to the first recess 6410 of the flexible printed circuit 641.

In some embodiments, a gap 650 is formed on the frame 65. When the interface element 643 is disposed in the accommodating space 60, the position of the gap 650 corresponds to the position of the interface 6433 of the interface element 643 so that the interface 6433 is exposed to the gap 650. Accordingly, the interface 6433 may receive an outside interface (not shown) through the gap 65.

In some embodiments, the battery 67 is disposed in the accommodating space 60 and electrically connected with the circuit structure 64. The electronic component 69 is disposed on the flexible printed circuit 641 and electrically connected with the flexible printed circuit 641. The elements, which includes the electronic component 69, disposed on and electrically connected to the flexible printed circuit 641 are all power by the battery 67. In some embodiments, the battery 67 is rechargeable.

In some embodiments, the interface 6433 of the interface element 643 exposed to the gap 650 of the frame 65 is used for receiving a charging source (not shown) to charge the battery 67. In some embodiments, the interface 6433 of the interface element 643 exposed to the gap 650 of the frame 65 is used for receiving an interface of an electronic device (not shown) to exchange data between the electronic component 69 and the electronic device.

In some embodiments, the first plate 61 includes a portion 611. The portion 611 is a part of the first plate 61. The portion 611 corresponds to a switch 691 of the electronic component 69. In other words, the location of the portion 611 formed on the first plate 611 corresponds to the location of the switch 691 of the electronic component 69 disposed in the accommodating space 60.

In particular, the portion 611 is a segment of the first plate 61. More specifically, as shown in FIGS. 6A, 6B and 6F, an area of the first plate 61 is partially segmented into the portion 611. The portion 611 is still attached to the first plate 61 because the portion 611 is not completely segmented from the first plate 61. Accordingly, when a user presses the portion 611, it may cause the portion 611 to lean against the corresponding switch 691 of the electronic component 69 to control the activation or inactivation of the electronic component 69.

In some embodiments, materials of the first plate 61, the second plate 63 and the frame 65 include metal or plastic. In some embodiments, the electronic component 69 includes a tracker having an antenna 693. To prevent the antenna 693 from being shielded (especially when the first plate 61, the second plate 63 and the frame 65 are made of metal), a hole 610 is formed on the first plate 61 for exposing the antenna 693. In other words, the location of the hole 610 formed on the first plate 41 corresponds to the location of the antenna 693 of the electronic component 69 disposed in the accommodating space 60. It should note that, in some embodiments, the holes for exposing the antenna of the electronic component may be formed on the second plate 63 when the antenna of the electronic component faces to the second plate 63.

In some embodiments, there may be another electronic component including a speaker 68 (e.g., a beeper). The speaker 68 may be electrically connected to the battery 67 via the flexible printed circuit 641 and powered by the battery 67. The speaker 68 may be configured to alert user for different conditions of the card-shape device 6. For example, when the card-shape device 6 is going to be out of battery, the speaker 68 alerts the user by beep sound. In some embodiments, to improve acoustical transmission of the sound from the speaker 68, a cavity 680 may be formed between the flexible printed circuit 641 and the speaker 68. In particular, the speaker 68 may be supported by a pad 681. An opening 682 may be formed on the pad 681 to connect the cavity 680 to outside space so that the acoustical transmission of the sound from the speaker 68 may be improved.

In some embodiments, the first plate 61 attaches to the frame 65 by an adhesive (not shown) disposed around a first surface 65S1 of the frame 65, and the second plate 63 attaches to the frame 65 by another adhesive (not shown) disposed around a second surface 65S2 of the frame 65.

In some embodiments, a thickness (e.g., thickness T10, T20, T30, T40 or T60 along the axis A11, A21, A31, A41 or A61) of the card-shape device (e.g., the card-shape device 1, 2, 3, 4 or 6) is between 0.5 mm (i.e., millimeter) to 3 mm. In some embodiments, the thickness of the card-shape device is between 1 mm to 2 mm. For example, the thickness of the card-shape device is equal to a thickness of a user card (e.g., a credit card, a debit card, a charge card, a prepaid card, an identification card, a drive license card, a health insurance card, etc.), and the thickness of the user card is about 0.5 mm to 1.5 mm or about 1 mm to 2 mm.

In some embodiments, a thickness of the first plate (e.g., the first plate 11, 21, 31, 41 or 61) is between 0.1 mm to 0.5 mm, a thickness of the second plate (e.g., the second plate 13, 23, 33, 43 or 63) is between 0.1 mm to 0.5 mm, and a thickness of the frame (e.g., the frame 15, 25, 35, 45 or 65) is between 0.3 mm to 2 mm.

In some embodiments, the frame (e.g., the frame 15, 25, 35, 45 or 65) has a ring shape. In some embodiments, the frame (e.g., the frame 15, 25, 35, 45 or 65) has a uniform width (e.g., the width W15, W25, W35, W45 or W65 along the axis A12, A22, A32, A42 or A62). For example, the uniform width is between 1 mm to 10 mm.

In some embodiments, the axes A11, A21, A31, A41 or A61 may be respectively perpendicular to the axes A12, A22, A32, A42 or A62.

It should be noted that the circuit structure 44 or 54 may be used in the card-shape devices 1, 2, 3, 4 or 6. It is not intended to limit the combinations of the circuit structures and the card-shape devices of the present invention. In addition, the electrical traces between the elements and components (e.g., flexible printed circuit, interface element, electronic component, battery etc.) mentioned in the above embodiments may be arranged inside the elements and the components.

In view of the foregoing, the card-shape device provided by the present invention can be introduced as a user card, such as a credit card, a debit card, a charge card, a prepaid card, an identification card, a drive license card, a health insurance card, etc. Because the card-shape device of the present invention includes an electronic component, such as a tracker, once the user card is lost or stolen, it can still be found back easily. The circuit structure provided by the present invention can be fitted in the card-shape device and enhance the robustness of the card-shape device when being used.

While this invention has been described with specific embodiments thereof, it is evident that many alternatives, modifications, and variations may be apparent to those skilled in the art. For example, various components of the embodiments may be interchanged, added, or substituted in the other embodiments. Also, all of the elements of each figure are not necessary for operation of the disclosed embodiments. For example, one of ordinary skill in the art of the disclosed embodiments would be enabled to make and use the teachings of the invention by simply employing the elements of the independent claims. Accordingly, embodiments of the invention as set forth herein are intended to be illustrative, not limiting. Various changes may be made without departing from the spirit and scope of the invention.

1. A circuit structure, comprising:
a flexible printed circuit, having:
a first recess at an edge of the flexible printed circuit; and
a plurality of first electrical contacts disposed around the first recess;
an interface element, having:
a body;
an interface, disposed on the body; and
a plurality of second electrical contacts, disposed on the body and electrically connected with the interface;
wherein the interface of the interface element includes a universal serial bus (USB) type-c interface, the interface of the interface element is exposed to the first recess of the flexible printed circuit when the first electrical contacts electrically connect to the second electrical contacts, so as to allow the interface of the interface element to connect to an external USB type-c connector.

2. (canceled)

3. The circuit structure of claim 1, wherein the interface of the interface element receives an outside interface along a direction, and the first electrical contacts disposed around the first recess along the same direction.

4. The circuit structure of claim 1, wherein the flexible printed circuit further has a protrusion protruded from a surface of the flexible printed circuit, and the interface element further has a through hole or a second recess for receiving the protrusion of the flexible printed circuit.

5. A card-shape device, comprising:
a first plate;
a second plate;
a frame disposed between the first plate and the second plate, wherein an accommodating space is defined by the first plate, the second plate and the frame; and
a circuit structure disposed in the accommodating space and comprising:
a flexible printed circuit, having:
a first recess at an edge of the flexible printed circuit; and
a plurality of first electrical contacts disposed around the first recess;
an interface element, having:
a body;
an interface, disposed on the body; and
a plurality of second electrical contacts, disposed on the body and electrically connected with the interface;
wherein the interface of the interface element includes a universal serial bus (USB) type-c interface, and the interface of the interface element is exposed to the first recess of the flexible printed circuit when the first electrical contacts electrically connect to the second electrical contacts, so as to allow the interface of the interface element to connect to an external USB type-c connector.

6. The card-shape device of claim 5, wherein a gap is formed on the frame for exposing the interface of the of the interface element.

7. The card-shape device of claim 5, further comprising:
a battery, disposed in the accommodating space and connected with the circuit structure; and
an electronic component, disposed on the flexible printed circuit and powered by the battery.

8. The card-shape device of claim 7, wherein the first plate includes:
a portion, corresponding to a switch of the electronic component.

9. The card-shape device of claim 8, wherein the portion is a segment of the first plate.

10. The card-shape device of claim 7, wherein the electronic component includes a tracker.

11. The card-shape device of claim 10, wherein a hole is formed on the first plate or the second plate for exposing an antenna of the tracker.

12. The card-shape device of claim 7, wherein the electronic component includes a speaker, and a cavity is formed between the speaker and the flexible printed circuit.

13. The card-shape device of claim 5, further comprising:
a chip, being configured to record personal information.

14. The card-shape device of claim 5, wherein the first plate attaches to the frame by an adhesive disposed around a first surface of the frame, and the second plate attaches to the frame by another adhesive disposed around a second surface of the frame.

15. The card-shape device of claim 5, wherein the card-shape device has a rectangular shape, a round shape or a triangular shape.

16. The card-shape device of claim 5, wherein the frame has a ring shape.

17. The card-shape device of claim 5, wherein the frame has a uniform width.

18. The card-shape device of claim 17, wherein the uniform width is between 1 mm to 10 mm.

19. The card-shape device of claim 5, wherein a thickness of the first plate is between 0.1 mm to 0.5 mm, a thickness of the second plate is between 0.1 mm to 0.5 mm and a thickness of the frame is between 0.3 mm to 2 mm.

20. (canceled)

21. An interface element, comprising:
a body;
an interface, disposed on the body; and
a plurality of first electrical contacts, disposed on the body and electrically connected with the interface, and configured to be bonded to a plurality of second electrical contacts of a flexible printed circuit;
wherein the interface includes a universal serial bus (USB) type-c interface, and the interface is exposed to a recess of the flexible printed circuit when the first electrical contacts electrically connect to the plurality of second electrical contacts of the flexible printed circuit, so as to allow the interface of the interface element to connect to an external USB type-c connector.
